(19) United States
(12) Patent Application Publication
(10) Pub. No.: US 2013/0134600 A1
(43) Pub. Date: May 30, 2013

(54) SEMICONDUCTOR DEVICE AND METHOD FOR MANUFACTURING THE SAME

(71) Applicants: Chih-Jing Hsu, Kaohsiung City (TW); Ying-Te Ou, Kaohsiung City (TW)

(72) Inventors: Chih-Jing Hsu, Kaohsiung City (TW); Ying-Te Ou, Kaohsiung City (TW)

(73) Assignee: ADVANCED SEMICONDUCTOR ENGINEERING, INC., Kaohsiung (TW)

(21) Appl. No.: 13/305,593

(22) Filed: Nov. 28, 2011

(51) Int. Cl. H01L 23/48; H01L 21/768

(52) U.S. Cl. 257/774; 438/675; 257/E23.011; 257/E21.586

(57) ABSTRACT

The present invention relates to a semiconductor device and method for manufacturing the same. The semiconductor device includes a substrate, a dielectric layer, a metal layer, an interconnection metal and an insulation circular layer. The substrate has at least one through hole. The dielectric layer is disposed adjacent to the substrate. The metal layer is disposed adjacent to the dielectric layer. The interconnection metal is disposed in the at least one through hole. An insulation circular layer surrounds the interconnection metal, wherein the insulation layer has an upper surface and the upper surface contacts the dielectric layer. Whereby, the metal layer can be electrically connected to another surface of the substrate through the interconnection metal.

### BACKGROUND OF THE INVENTION

1. Field of the Invention

The present invention relates generally to the field of semiconductor packaging, and, more particularly, to 3D semiconductor packaging employing through silicon via (TSV) technology.

2. Description of the Related Art

In a conventional method for making a stacked semiconductor device, conductive vias are first formed in a semiconductor wafer. The conductive vias are then exposed at both the top and bottom surfaces of the semiconductor wafer. Thereafter, a dielectric layer and a metal layer are formed in sequence on the top surface or, alternatively, on the bottom surface of the semiconductor wafer. However, where the dielectric layer and metal layer are already formed on the semiconductor wafer, this method cannot be used.

### SUMMARY OF THE INVENTION

One aspect of the disclosure relates to a semiconductor device. In one embodiment, the semiconductor device includes a substrate having at least one conductive via formed therein, the at least one conductive via including an interconnection metal and an insulation layer surrounding the interconnection metal; a dielectric layer disposed on a first surface of the substrate and covering at least a portion of an upper surface of the insulation layer; and a metal layer disposed adjacent the dielectric layer and electrically connected to the metal layer. In an embodiment, the interconnection metal penetrates the dielectric layer to electrically connect with the interconnection metal but the insulation layer does not extend through the dielectric layer. The insulation layer can be entirely covered by the dielectric layer. In various embodiments, the interconnection metal is cup-shaped, wherein the interconnection metal includes a horizontal portion substantially parallel to the first surface, the horizontal portion closer to the first surface than to a second surface of the substrate opposite to the first surface. The cup-shaped interconnection metal defines an interior portion, the interior portion having an insulation material disposed therein. In other embodiments, the interconnection metal is a metal pillar. In an embodiment, the dielectric layer has a recess portion, the depth of the recess portion less than the thickness of the dielectric layer, the insulation layer extending partly into the recess portion. In an embodiment, the dielectric layer has an opening, wherein part of the metal layer is disposed in the opening of the dielectric layer to contact the interconnection metal.

Another aspect of the disclosure relates to manufacturing methods. In one embodiment, a method for forming a semiconductor device includes the steps of etching a substrate to form a cylindrical cavity; depositing an interconnection metal in the cylindrical cavity; etching the substrate to form a cylindrical hole, wherein the interconnection metal is disposed within the cylindrical hole; and depositing an insulation layer into the cylindrical hole to form an insulation circular layer, wherein the insulation circular layer has an upper dielectric layer has an opening. The interconnection metal is formed on a sidewall of the cylindrical cavity, so as to form a shape of a cup and defines a central groove; an insulation circular layer is formed in the circular groove, and a central insulation material is formed in the central groove. In an embodiment, the metal layer is further disposed in an opening of the dielectric layer; and the cylindrical cavity exposes a part of the metal layer.

### BRIEF DESCRIPTION OF THE DRAWINGS

FIG. 1 illustrates a cross-sectional view of a semiconductor device having a conductive via according to an embodiment of the present invention;

FIGS. 2 to 5 illustrate a method for making the semiconductor device of FIG. 1 according to an embodiment of the present invention;

FIGS. 6 to 9 illustrate a method for making the semiconductor device of FIG. 1 according to another embodiment of the present invention;

FIG. 10 illustrates a method for making the semiconductor device of FIG. 1 according to another embodiment of the present invention;

FIG. 11 illustrates a cross-sectional view of a semiconductor device having a conductive via according to another embodiment of the present invention;

FIGS. 12 to 13 illustrate a method for making the semiconductor device of FIG. 11 according to an embodiment of the present invention;

FIG. 14 illustrates a cross-sectional view of a semiconductor device having a conductive via according to another embodiment of the present invention;

FIG. 15 illustrates a cross-sectional view of a semiconductor device having a conductive via according to another embodiment of the present invention;

FIG. 16 illustrates a method for making the semiconductor device of FIG. 15 according to an embodiment of the present invention;

FIG. 17 illustrates a method for making the semiconductor device of FIG. 15 according to another embodiment of the present invention;

FIG. 18 illustrates a cross-sectional view of a semiconductor device having a conductive via according to an embodiment of the present invention;

FIG. 19 illustrates a method for making the semiconductor device of FIG. 18 according to an embodiment of the present invention; and

FIG. 20 illustrates a cross-sectional view of a semiconductor device having a conductive via according to another embodiment of the present invention.

Common reference numerals are used throughout the drawings and the detailed description to indicate the same elements. The present invention will be more apparent from the following detailed description taken in conjunction with the accompanying drawings.

### DETAILED DESCRIPTION OF THE INVENTION

Referring to FIG. 1, a cross-sectional view of a semiconductor device 1, according to an embodiment of the present invention, is illustrated. The semiconductor device 1 comprises a wafer 10 and a conductive via 26 formed therein. The wafer 10 includes a substrate 11, a dielectric layer 12 and a metal layer 13. In this embodiment, the material of the substrate 11 is a semiconductor material such as silicon or germanium. However, in other embodiments, the material of the substrate 11 may be glass. The substrate 11 has a first surface 111, a second surface 112 and a through hole 114.

As depicted in FIG. 1, the dielectric layer 12 is disposed on the first surface 111 of the substrate 11, and has an opening 121 to expose a part of the metal layer 13. The position of the opening 121 corresponds to that of the conductive via 26. In this embodiment, the dielectric layer 12 includes a polymer such as polyimide (PI) or polypropylene (PP). However, in other embodiments, the material of the dielectric layer 12 can be silicon oxide or silicon nitride. The metal layer 13 is disposed on the dielectric layer 12. In this embodiment, the material of the metal layer 13 is copper.

As illustrated in FIG. 1, the conductive via 26 includes an insulation layer 22, an interconnection metal 24 and a central insulation material 25. The interconnection metal 24 is disposed in the through hole 114 of the substrate 11, and contacts the metal layer 13 to ensure an electrical connection. In this embodiment, the interconnection metal 24 extends across the opening 121 of the dielectric layer 12 to contact the metal layer 13. The interconnection metal 24 is cup-shaped and defines a central portion 241, and the central insulation material 25 is disposed in the central portion 241.

In this embodiment, the insulation layer 22 is disposed between the interconnection metal 24 and a sidewall of the through hole 114, and surrounds the interconnection metal 24. The material of the insulation circular layer 22 can be a polymer which can be the same as the central insulation material 25. The insulation layer 22 extends to the dielectric layer 12, that is, the insulation layer 22 has an upper surface and the upper surface contacts the dielectric layer 12, and the insulation layer 22 does not extend into the dielectric layer 12. As measured vertically through the substrate 11 (from the first surface 111 to the second surface 112), the length of the insulation layer 22 is less than that of the interconnection metal 24.

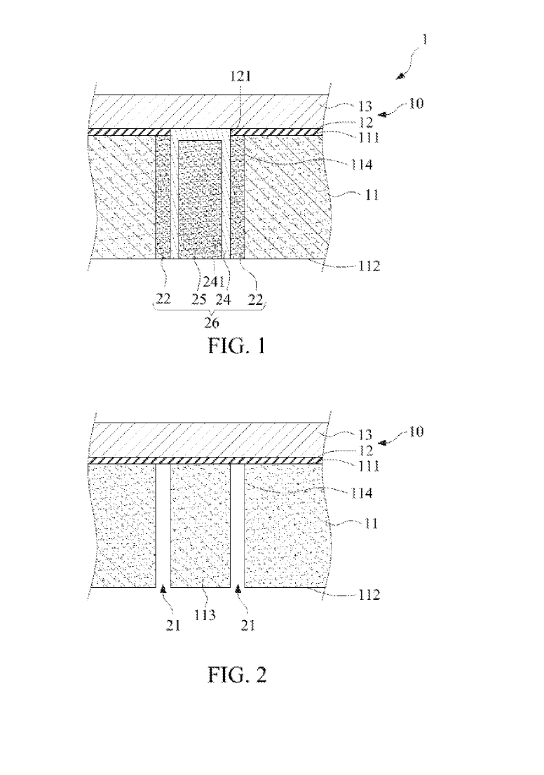

Referring to FIGS. 2 to 5, a method for making the semiconductor device 1, according to an embodiment of the present invention, is illustrated.

Referring to FIG. 2, the wafer 10 is provided. The wafer 10 has the substrate 11, the dielectric layer 12 and the metal layer 13. In this embodiment, the material of the substrate 11 is a semiconductor material such as silicon or germanium. However, in other embodiments, the material of the substrate 11 may be glass. The substrate 11 has a first surface 111 and a second surface 112. The dielectric layer 12 is disposed on the first surface 111 of the substrate 11. In this embodiment, the dielectric layer 12 includes a polymer, such as polyimide (PI) or polypropylene (PP). However, in other embodiments, the material of the dielectric layer 12 may be silicon dioxide (SiO₂). The metal layer 13 is disposed on the dielectric layer 12. In this embodiment, the material of the metal layer 13 is copper.

As illustrated in FIG. 2, a cylindrical hole 21 is formed from the second surface 112 of the substrate 11 by etching. The cylindrical hole 21 penetrates through the substrate 11 to expose a part of the dielectric layer 12, and surrounds a central portion 113 of the substrate 11. The outer sidewall of the cylindrical hole 21 defines the through hole 114 of the substrate 11.

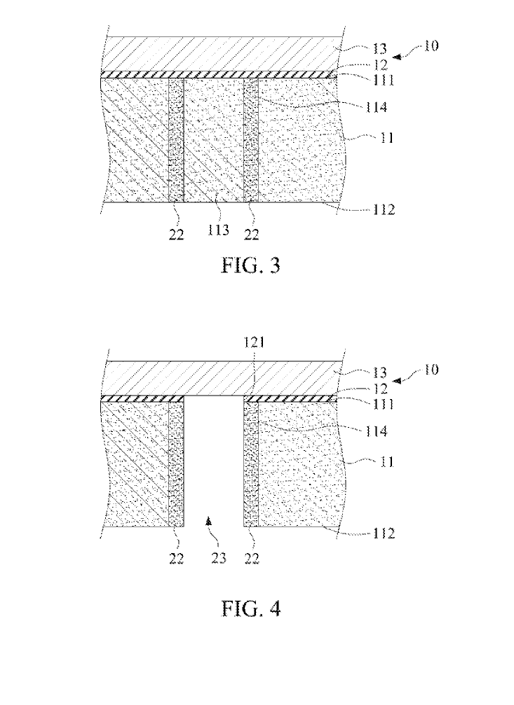

Referring to FIG. 3, an insulation layer is formed in the cylindrical hole 21 so as to form the insulation layer 22. In this embodiment, the material of the insulation circular layer 22 is a polymer.

Referring to FIG. 4, the central portion 113 of the substrate 11 is removed by etching so as to form a cylindrical cavity 23. In this embodiment, a portion of the dielectric layer 12 corresponding to the central portion 113 of the substrate 11 is further removed to form an opening 121, so that the cylindrical cavity 23 exposes a part of the metal layer 13.

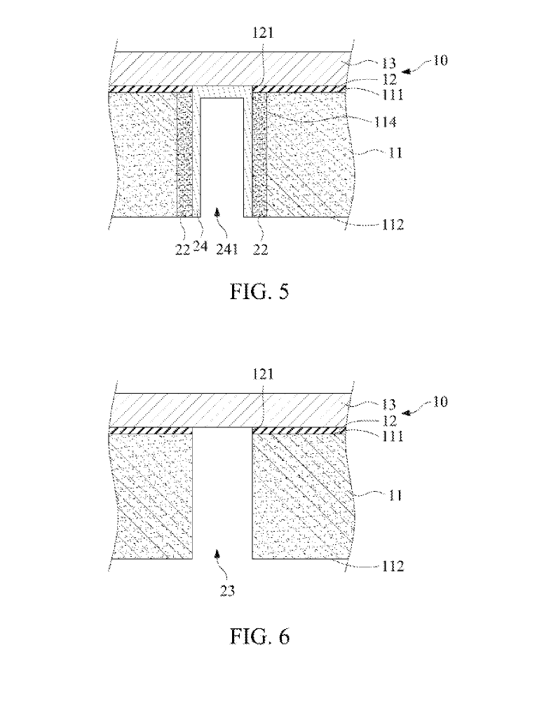

Referring to FIG. 5, the interconnection metal 24 is formed on the interior surfaces of the cylindrical cavity 23, and contacts the metal layer 13. In this embodiment, the interconnection metal 24 is formed on the sidewall of the cylindrical cavity 23 and on a surface of the metal layer 13 in a shape of a cup, and defines the central portion 241. The horizontal portion of the interconnection metal 24 contacts the metal layer 13, and the central portion 241 has an opening on the second surface 112 of the substrate 11. Then, a central insulation material 25 is formed in the central portion 241 (shown in FIG. 1), so as to complete the conductive via 26, and the semiconductor device 1 is formed.

In this embodiment, although the wafer 10 has the dielectric layer 12 and the metal layer 13 formed on the first surface 111 of the substrate 11 at the initial step, the interconnection metal 24 is formed from the second surface 112 of the substrate 11. Therefore, the metal layer 13 can be electrically connected to the second surface 112 of the substrate 11 through the interconnection metal 24.

Referring to FIGS. 6 to 9, a method for making the semiconductor device 1, according to another embodiment of the present invention, is illustrated.

Referring to FIG. 6, the wafer 10 is provided. The wafer 10 is the same as the wafer 10 in FIG. 2. Then, a portion of the substrate 11 is removed from its second surface 112 so as to form a cylindrical cavity 23 that penetrates through the substrate 11. In this embodiment, a portion of the dielectric layer 12 corresponding to the cylindrical cavity 23 is further removed to form the opening 121 in the dielectric layer 12, so that the cylindrical cavity 23 exposes a part of the metal layer 13.

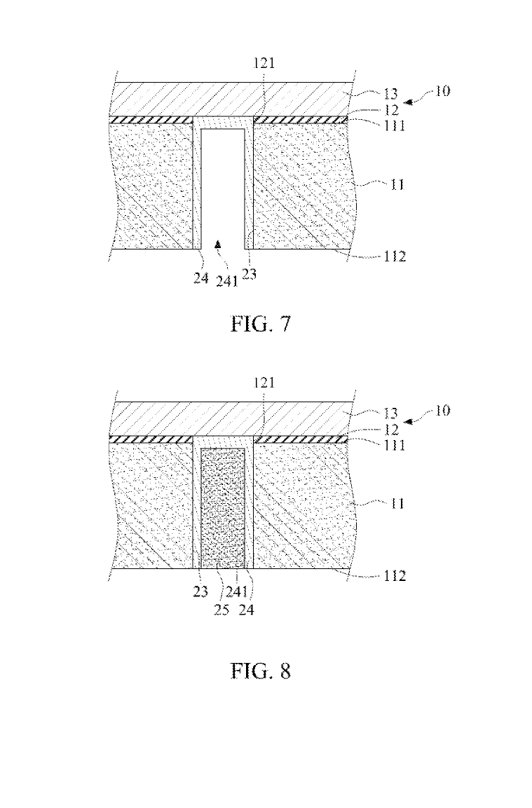

Referring to FIG. 7, the interconnection metal 24 is formed in the cylindrical cavity 23 by metal deposition, and contacts the metal layer 13. In this embodiment, the interconnection metal 24 is formed on the sidewall of the cylindrical cavity 23. Thus, the interconnection metal 24 is in a shape of cup and defines a central portion 241. The horizontal portion of the interconnection metal 24 contacts the metal layer 13, and the central portion 241 has an opening on the second surface 112 of the substrate 11.

Referring to FIG. 8, the central insulation material 25 is formed in the central portion 241.

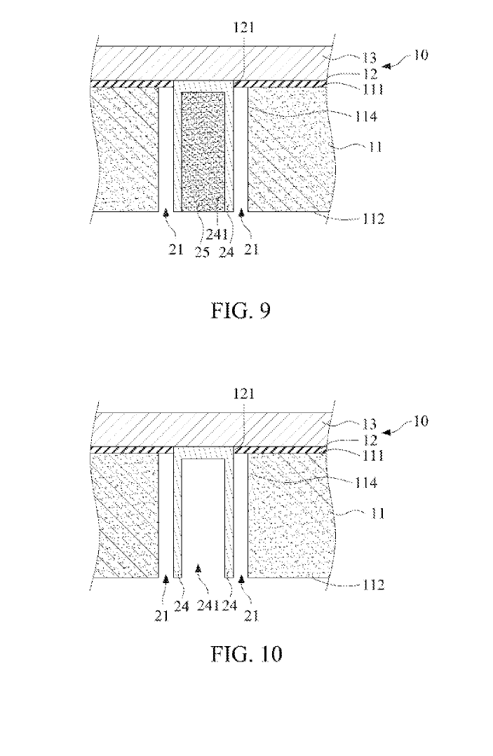

Referring to FIG. 9, the cylindrical hole 21 is formed from the second surface 112 of the substrate 11. The cylindrical hole 21 penetrates through the substrate 11 to expose a part of the dielectric layer 12, and surrounds the interconnection metal 24. Meanwhile, the outer sidewall of the cylindrical hole 21 defines the through hole 114 of the substrate 11. Then, an insulation material is deposited in the cylindrical hole 21 to form an insulation circular layer 22, and the semiconductor device 1 is formed.

Referring to FIG. 10, a method for making the semiconductor device 1 according to another embodiment of the present invention is illustrated. The method of this embodiment is substantially the same as the method of FIGS. 6 to 9, the difference described below.

Referring to FIG. 10, when the interconnection metal 24 is formed on the sidewall of the cylindrical cavity 23, the central insulation material 25 is not thereafter formed in the central portion 241 (as in the previous embodiment, shown in FIG. 8). Instead, in this embodiment, the cylindrical hole 21 is then formed from the second surface 112 of the substrate 11. The cylindrical hole 21 penetrates through the substrate 11 to expose a part of the dielectric layer 12, and surrounds the interconnection metal 24. Then, an insulation material is applied to the central portion 241 and the cylindrical hole 21 at substantially the same time, wherein the insulation material disposed in the central portion 241 is defined as the central insulation material 25, and the insulation material disposed in the cylindrical hole 21 is defined as the insulation circular layer 22, as shown in FIG.1.

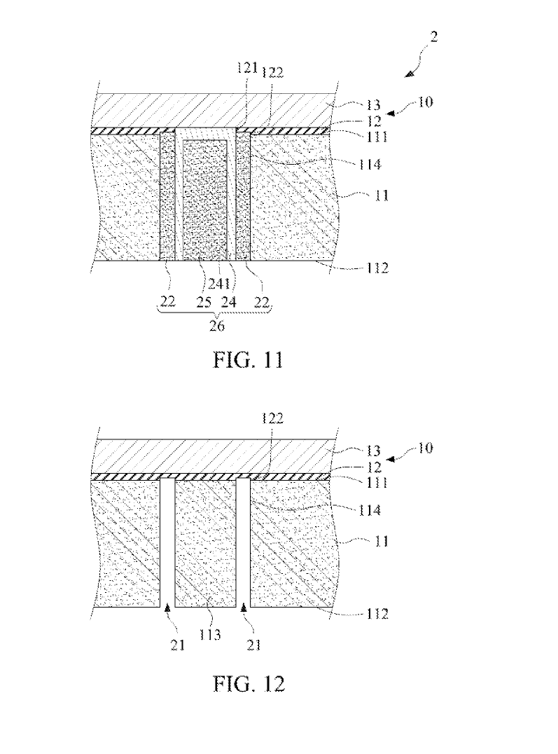

Referring to FIG. 11, a cross-sectional view of a semiconductor device according to another embodiment of the present invention is illustrated. The semiconductor device 2 of this embodiment is substantially the same as the semiconductor device 1 of FIG. 1, and the same elements are designated with same reference numerals. The difference between the semiconductor device 2 of this embodiment and the semiconductor device 1 of FIG. 1 is that the dielectric layer 12 further has a recess portion 122. The depth of the recess portion 122 is less than the thickness of the dielectric layer 12, that is, the recess portion 122 dose not penetrate through the dielectric layer 12. The position of the recess portion 122 corresponds to the insulation circular layer 22, and the insulation circular layer 22 extends into the recess portion 122.

Referring to FIGS. 12 to 13, a method for making the semiconductor device 2, according to an embodiment of the present invention, is illustrated. The method of this embodiment is substantially the same as the method of FIGS. 2 to 5, the difference described below.

Referring to FIG. 12, the wafer 10 is provided. The wafer 10 is the same as the wafer 10 in FIG. 2. Then, a cylindrical hole 21 is formed from the second surface 112 of the substrate 11. The cylindrical hole 21 penetrates through the substrate 11 to expose a part of the dielectric layer 12, and surrounds a central portion 113 of the substrate 11. In this embodiment, a part of the dielectric layer 12 is further removed. Thus, the cylindrical hole 21 further extends into the dielectric layer 12, so as to form a recess portion 122. The depth of the recess portion 122 is less than the thickness of the dielectric layer 12. Accordingly, the recess portion 122 does not penetrate through the dielectric layer 12.

Referring to FIG. 13, the insulation circular layer 22 is formed in the cylindrical hole 21. In this embodiment, the insulation circular layer 22 is further formed in the recess portion 122. The subsequent steps of this embodiment are the same as the steps of FIGS. 4 to 5, so that the semiconductor device 2 is formed.

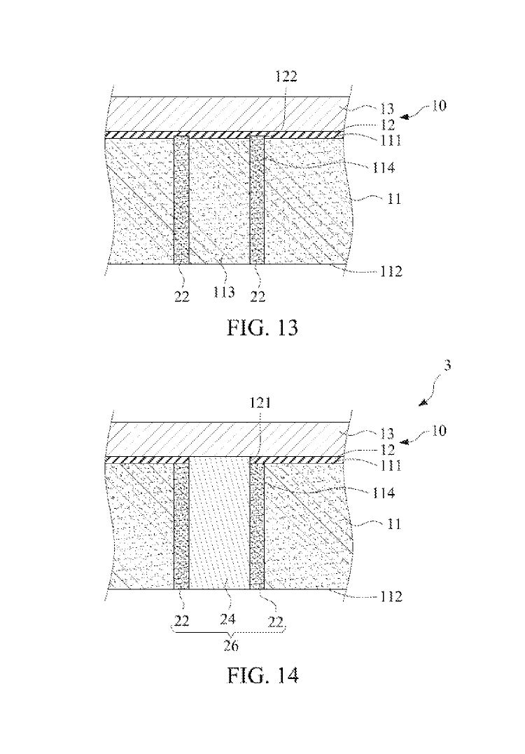

Referring to FIG. 14, a cross-sectional view of a semiconductor device 3, according to an embodiment of the present invention, is illustrated. The semiconductor device 3 of this embodiment is substantially the same as the semiconductor device 1 of FIG. 1, and the same elements are designated with same reference numerals. The difference between the semiconductor device 3 of this embodiment and the semiconductor device 1 of FIG. 1 is the structure of the conductive via 26. In this embodiment, when the interconnection metal 24 is formed in the cylindrical cavity 23, it fills the cylindrical cavity 23 to form a solid pillar structure. It is be understood that the interconnection metal 24 of the conductive via 26 of the semiconductor device 2 (FIG. 11) may be a solid pillar, too.

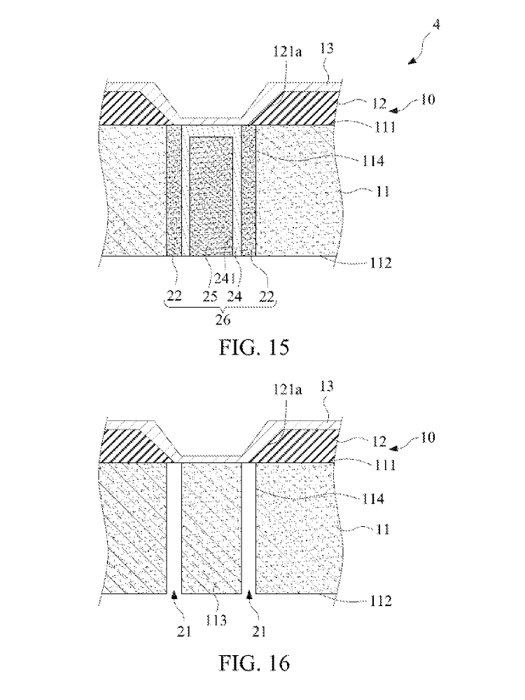

Referring to FIG. 15, a cross-sectional view of a semiconductor device 4, according to another embodiment of the present invention, is illustrated. The semiconductor device 4 of this embodiment is substantially the same as the semiconductor device 1 of FIG. 1, and the same elements are designated with same reference numerals. The differences between the semiconductor device 4 of this embodiment and the semiconductor device 1 of FIG. 1 are the structure of the metal layer 13 and the length of the interconnection metal 24. In this embodiment, the dielectric layer 12 has an opening 121a, and the metal layer 13 is disposed in the opening 121a of the dielectric layer 12 to contact the conductive conductive via 26. The conductive via 26 does not extend into the opening 121a. As measured vertically through the substrate 11 (from the first surface 111 to the second surface 112), the length of the insulation layer 22 is equal to that of the interconnection metal 24.

Referring to FIG. 16, a method for making the semiconductor device 4, according to another embodiment of the present invention, is illustrated. The method of this embodiment is substantially the same as the method of FIGS. 2 to 5, the difference described below.

Referring to FIG. 16, the wafer 10 is provided. The wafer 10 has the substrate 11, the dielectric layer 12 and the metal layer 13. The substrate 11 is the same as the substrate 11 of the FIG. 2. The dielectric layer 12 is disposed on the first surface 111 of the substrate 11, and has an opening 121a. The metal layer 13 is disposed on the dielectric layer 12 and in its opening 121a. Then, a cylindrical hole 21 is formed from the second surface 112 of the substrate 11. The cylindrical hole 21 penetrates through the substrate 11 to expose a part of the metal layer 13 and a part of the dielectric layer 12, and surrounds a central portion 113 of the substrate 11. The subsequent steps of this embodiment are the same as the steps of FIGS. 3 to 5, so that the semiconductor device 4 is formed.

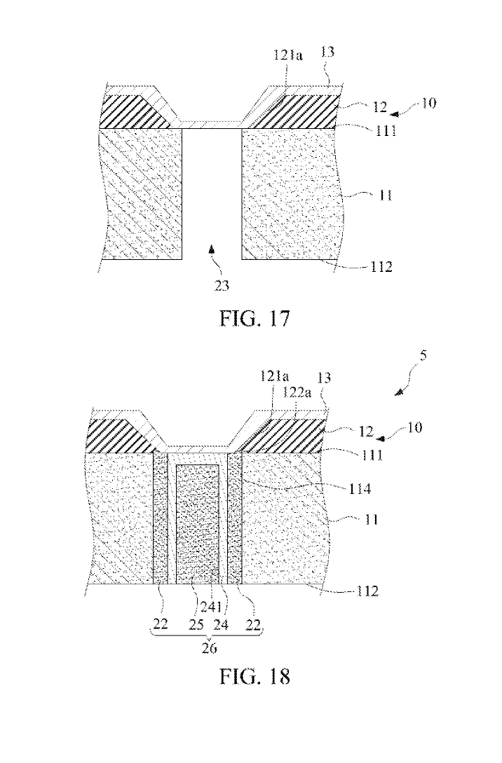

Referring to FIG. 17, a method for making the semiconductor device 4, according to another embodiment of the present invention, is illustrated. The method of this embodiment is substantially the same as the method of FIGS. 6 to 9, the difference described below.

Referring to FIG. 17, the wafer 10 is provided. The wafer 10 has the substrate 11, the dielectric layer 12 and the metal layer 13. The substrate 11 is the same as the substrate 11 of FIG. 16. The dielectric layer 12 is disposed on the first surface 111 of the substrate 11, and has an opening 121a. The metal layer 13 is disposed on the dielectric layer 12 and in its opening 121a. Then, a portion of the substrate 11 is removed from its second surface 112 so as to form a cylindrical cavity 23 that penetrates through the substrate 11. In this embodiment, the cylindrical cavity 23 exposes a part of the metal layer 13. The subsequent steps of this embodiment are the same as the steps of FIGS. 7 to 9, so that the semiconductor device 4 is formed.

Referring to FIG. 18, a cross-sectional view of a semiconductor device 5, according to another embodiment of the present invention, is illustrated. The semiconductor device 5 of this embodiment is substantially the same as the semiconductor device 4 of FIG. 15, and the same elements are designated with same reference numerals. The difference between the semiconductor device 5 of this embodiment and the semiconductor device 4 of FIG. 15 is that the dielectric layer 12 further has the recess portion 122. The depth of the recess portion 122 is less than the thickness of the dielectric layer 12. Accordingly, the recess portion 122 dose not penetrate through the dielectric layer 12.

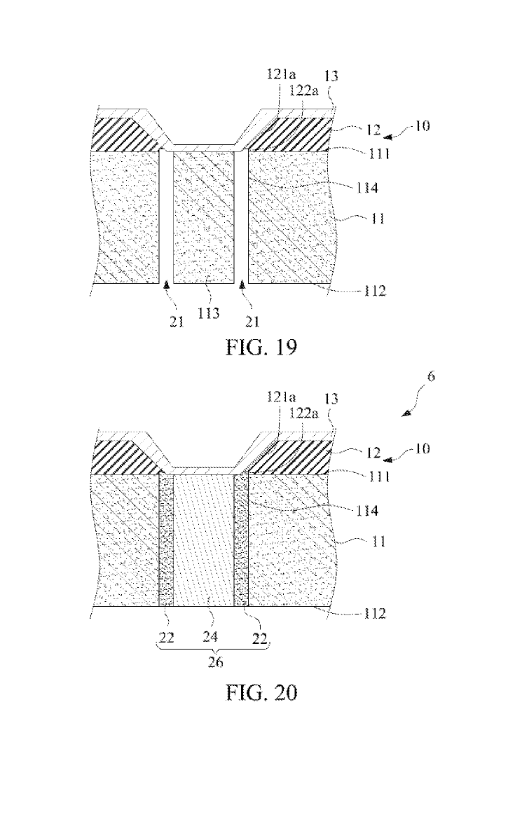

Referring to FIG. 19, a method for making the semiconductor device 5, according to an embodiment of the present invention, is illustrated. The method of this embodiment is substantially the same as the method of FIG. 16, the difference described below.

Referring to FIG. 19, the wafer 10 is provided. The wafer 10 is the same as the wafer 10 in FIG. 16. Then, a cylindrical hole 21 is formed from the second surface 112 of the substrate 11. In this embodiment, a part of the dielectric layer 12 is further removed. Thus, the cylindrical hole 21 further extends into the dielectric layer, so as to form the recess portion 122. The cylindrical hole 21 penetrates through the substrate 11 to expose a part of the metal layer 13 and a part of the dielectric layer 12. The subsequent steps of this embodiment are the same as the steps of FIGS. 3 to 5, so that the semiconductor device 5 is formed.

Referring to FIG. 20, a cross-sectional view of a semiconductor device 6, according to another embodiment of the present invention, is illustrated. The semiconductor device 6 of this embodiment is substantially the same as the semiconductor device 5 of FIG. 18, and the same elements are designated with same reference numerals. The difference between the semiconductor device 6 of this embodiment and the semiconductor device 5 is the structure of the conductive via 26. In this embodiment, the interconnection metal 24 of the conductive via 26 is a solid pillar. It is understood that the interconnection metal 24 of the conductive via 26 of the semiconductor device 4 (FIG. 15) may be a solid pillar, too.

While the invention has been described and illustrated with reference to specific embodiments thereof, these descriptions and illustrations do not limit the invention. It should be understood by those skilled in the art that various changes may be made and equivalents may be substituted without departing from the true spirit and scope of the invention as defined by the appended claims. The illustrations may not be necessarily be drawn to scale. There may be distinctions between the artistic renditions in the present disclosure and the actual apparatus due to manufacturing processes and tolerances. There may be other embodiments of the present invention which are not specifically illustrated. The specification and the drawings are to be regarded as illustrative rather than restrictive. Modifications may be made to adapt a particular situation, material, composition of matter, method, or process to the objective, spirit and scope of the invention. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the invention. Accordingly, unless specifically indicated herein, the order and grouping of the operations are not limitations of the invention.

What is claimed is:

1. A semiconductor device, comprising:
a substrate having at least one conductive via formed therein, the at least one conductive via including an interconnection metal and an insulation layer surrounding the interconnection metal;
a dielectric layer disposed on a first surface of the substrate and covering at least a portion of an upper surface of the insulation layer; and
a metal layer disposed adjacent the dielectric layer and electrically connected to the interconnection metal.

2. The semiconductor device of claim 1, wherein the interconnection metal extends through the dielectric layer to electrically connect with the metal layer.

3. The semiconductor device of claim 1, wherein the interconnection metal extends through the dielectric layer to electrically connect with the metal layer but the insulation layer does not extend through the dielectric layer.

4. The semiconductor device of claim 1, wherein the upper surface of the insulation layer is entirely covered by the dielectric layer.

5. The semiconductor device of claim 1, wherein the upper surface of the insulation layer is entirely covered by the dielectric layer and the metal layer.

6. The semiconductor device of claim 1, wherein the interconnection metal is cup-shaped.

7. The semiconductor device of claim 6, wherein the cup-shaped interconnection metal includes a side portion adjacent the insulation layer and a horizontal portion disposed on the metal layer.

8. The semiconductor device of claim 6, wherein the cup-shaped interconnection metal defines an interior portion, the interior portion having an insulation material disposed therein.

9. The semiconductor device of claim 1, wherein the interconnection metal is a metal pillar.

10. The semiconductor device of claim 1, wherein the dielectric layer has a recess portion, the depth of the recess portion less than the thickness of the dielectric layer, the insulation layer extending partly into the recess portion.

11. The semiconductor device of claim 1, wherein the dielectric layer has an opening, wherein part of the metal layer is disposed in the opening of the dielectric layer to contact the interconnection metal.

12. The semiconductor device of claim 1, wherein the material of the substrate includes silicon.

13. The semiconductor device of claim 1, wherein the material of the substrate includes glass.

14. A semiconductor device, comprising:
a substrate having at least one conductive via, the at least one conductive via including a through hole formed in the substrate, the through hole including an insulation layer disposed on a sidewall of the through hole and surrounding a cup-shaped interconnection metal;
a dielectric layer disposed on a first surface of the substrate; and
a metal layer disposed adjacent the dielectric layer;
wherein the interconnection metal extends through the dielectric layer to electrically connect with the metal layer but the insulation layer does not extend through the dielectric layer.

15. The semiconductor device of claim 14, wherein an upper surface of the insulation layer is entirely covered by the dielectric layer.

16. The semiconductor device of claim 14, wherein an upper surface of the insulation layer is entirely covered by the dielectric layer and the metal layer.

17. The semiconductor device of claim 14, wherein the interconnection metal defines an interior portion, the interior portion having an insulation material disposed therein.

18. A method for forming a semiconductor device, comprising the steps of:
etching a substrate to form a cylindrical cavity;
depositing an interconnection metal in the cylindrical cavity;
etching the substrate to form a cylindrical hole, wherein the interconnection metal is disposed within the cylindrical hole; and
depositing an insulation layer into the cylindrical hole to form an insulation layer, wherein the insulation layer has an upper surface and the upper surface thereby contacts a dielectric layer disposed on the substrate.

19. The method of claim 18, wherein the dielectric layer has an opening, the metal layer is further disposed in the opening of the dielectric layer; and the cylindrical cavity exposes a part of the metal layer.

20. The method of claim 18, wherein the interconnection metal is formed on a sidewall of the cylindrical cavity, so as to form a shape of a cup and defines a central portion; an insulation circular layer is formed in the circular portion, and a central insulation material is formed in the central portion.
